(19) United States
(12) Patent Application Publication
(10) Pub. No.: US 2025/0210966 A1
(43) Pub. Date: Jun. 26, 2025

(54) PROTECTION DEVICE FOR A HEATABLE CLOTHING GARMENT SUBMERGED IN WATER

(71) Applicant: Sailport AB, Saltsjö-Boo (SE)

(72) Inventors: Jakob KUTTENKEULER, Saltsjö-Boo (SE); Mikael RAZOLA, Saltsjö-Boo (SE)

(21) Appl. No.: 18/851,900

(22) PCT Filed: Apr. 3, 2023
(86) PCT No.: PCT/SE2023/050300

§ 371 Date: Sep. 27, 2024

(30) Foreign Application Priority Data
Apr. 7, 2022 (SE) 2250439-3

(51) Int. Cl. H02H 3/26; A41D 13/005; G01R 19/10; G01R 19/165; G01R 31/52; H02H 1/00; H05B 1/02

(52) U.S. Cl. CPC H02H 3/26; A41D 13/005; G01R 19/10; G01R 19/16576; G01R 31/52; H02H 1/0007; H05B 1/0272

(57) ABSTRACT

The present invention relates to a protection device for controlling a power supply circuit for powering a heating arrangement belonging to a heatable clothing garment, where the protection device, first power supply circuit, and clothing garment are adapted to be submerged in a body of water with its user. The protection device is adapted to detect a leaked electric current from the heating arrangement into the body of a user of the clothing garment. The protection device includes a controller adapted to adjust the power supply circuit upon receiving an output signal indicating a leaked current, and a self-test device configured to verify the functionality of the protection device, where the galvanic contact between a testing electrode and the body of the user goes through the body of water.

### TECHNICAL FIELD

The present invention relates to a protection device for controlling a power supply circuit for powering a heating arrangement belonging to a heatable clothing garment where the protection device, first power supply circuit, and clothing garment are adapted to be submerged in a body of water with its user.

### PRIOR ART

Electrically heatable clothing may be designed for cold climate activities, such as diving. While normal insulation garments works by hindering dissipation of the heat that a body produces by insulation, an electrically heatable clothing garment generates heat independent of the body of a user. Normal insulation strategies may stop functioning if the clothing garment becomes wet from underwater activities, or if the body stops moving, thereby generating less heat. In such scenarios an electrically heatable clothing garment may be preferable.

The main challenge in high-powered electrically heated garments is the risk of electrical leakage that potentially can cause discomfort and/or injuries to the user. A commonly used method to mitigate this risk posed by leaked electric current is to limit the power (i.e. by limiting voltage) supplied to the heating element to a level which is sufficiently low not to pose a risk to the user. This means, though, that the voltage supplied to the heating arrangement is not enough to ensure the comfort of the user in extreme cold-climate conditions. One way to account for the low power supply is to provide additional thermal insulation, such solutions are however expensive and result in unduly cumbersome clothing hindering maneuverability.

A further challenge in the design of heatable clothing is to enable an even heat distribution provided by the heating arrangement. Prior electrically heatable clothing predominately produce heat in patches of local heat-elements, leaving cold spots in the areas between the heating elements. This problem is accentuated in electrically heated diving suits since external hydrostatic pressure is increased, pushing the heating elements tightly to the skin of the user.

It is known that water in various forms have a detrimental effect on electrical equipment. International Standard IEC 60529 outlines an international classification system that describes the sealing characteristics of electrical equipment. The classification system uses the “Ingress Protection” code, the “IP” code, to define the level of seal, where the second of two numerical digits represent moisture protection. IPx8 is the highest level of protections and indicates equipment for continuous immersion in water.

In an underwater application there is a need for high heating capacity and thus a need for high voltages and electrical currents through the heating elements of the garment. The combination of high voltages/electrical currents and underwater applications is a high risk application if there is a malfunction and electrical power can reach the user. Hence, high power heating under water require a protection device that will assure the security of the user and that can be classified IPx8.

Patent publication U.S. Pat. No. 10,893,576 discloses a heating system embedded in a wearable garment, comprising at least one heating element with a sense wire for detecting and providing a signal indicative of a safety condition, and a controller connected to the heating element and to the sense wire and configured to shut down the heating element in response to the signal indicative of the safety condition.

Patent publication WO 2019/243379 discloses a protective device with increased safety, for protecting a person against electric shock resulting from unintentional contact with parts under voltage or parts carrying current in a wearable garment. At least one electrode is connected to the evaluation unit via at least two signal lines and a test unit is provided in the protective device, which test unit feeds an electrical test signal into a first signal line connected to the electrode and the test unit receives the test response signal transmitted via the electrode and a second signal line connected to the electrode and evaluates the test response signal in a test evaluation unit, and the test unit indicates the functional reliability of the protective device according to the received test response signal.

Patent publication US 2015/060430 A1 discloses a heat retaining jacket where certain precautions have been made to protect the power circuit from overload and the battery from overdischarge. The jacket comprises an adapter connected to a heating element and a battery, wherein the adapter is provided with an overload protection circuit to cut off the current when a load current of the battery or for the electric power tool exceeds a predetermined value. Further there is provided an overdischarge protection circuit to cut off the current when a voltage of the battery for the electric power tool decreases below a predetermined value.

### SUMMARY OF THE PRESENT INVENTION

### Problems

A challenge in the design of electrically heatable clothing garments is to ensure the safety of a user from leaked current from a heating element in the scenario of a malfunction.

It is a technical problem to provide sufficient power into an electrically heatable clothing garment to enable the heating in extreme whether scenarios or cold climate conditions without putting the user into jeopardy due to the relatively high voltage supplied to the heating arrangements.

There is a risk with heated garments for normal use above water where there is a malfunction, such as a heat conductor with a damaged insulation causing a physical contact between the conductor and the body of the user. This will cause electrical shock if the electrical power is high enough.

However, the risk of electrical shock when the user with the heated garment is submerged into water is much larger since any damage on the insulation that will expose the electrical conductors to the water will cause a leaked current from the open conductor through the water and into the body of the user. Hence, the safety arrangement for underwater applications must be more robust and adapted to the use under water.

It is a technical problem to protect a user wearing an electrically heated clothing garment against leaked electrical current in the occurrence of a malfunction. More specifically, it is a technical problem to supply an electrically heatable clothing garment with a voltage and current potentially not safe for humans and protect the user against a leaked current in the occurrence of a malfunction. In such a malfunction it is a problem to reliably detect leaked current passing through a person in the occurrence of a malfunction.

In the scenario of using an electrode and comparator as proposed by this invention it is a technical problem to improve the accuracy in which leaked current can be detected.

It is an also a problem that protection mechanisms or devices for preventing electrical shocks may malfunction, as such it is a technical problem to test the function of the protection mechanism. It is also a problem to provide additional protection mechanisms in case of a malfunction of a primary protection mechanism.

### Solution

The present invention alleviates, to a great extent, the disadvantages of prior devices by providing a protection device for controlling a first power supply circuit for powering a heating arrangement belonging to a heatable clothing garment where the protection device, first power supply circuit, and clothing garment are adapted to be submerged in a body of water with its user. The protection device is adapted to detect a leaked electric current from the heating arrangement into the body of a user of the clothing garment.

The protection device comprises a controller adapted to receive a first output signal, and to adjust the first power supply circuit when the first output signal indicates a difference in electrical potential exceeding a threshold value, the potential difference being caused by a leaked current, leaked from the heating arrangement.

The protection device further comprise a self-test device configured to verify the functionality of the protection device and a correct galvanic contact between the sensing electrode and the skin of the user.

It is proposed that the self-test device comprises a testing electrode adapted to enable a galvanic contact with the body of the user through the body of water.

The self-test device is be configured to operate in either a non-testing mode or a testing mode. When in the non-testing mode, the testing electrode may be at an electrically floating potential. When in the testing mode, the self-test device may be configured to set the testing electrode at a certain electrical potential different from ground that exceeds the threshold value, thus generating an electrical closed-circuit test current simulating a leaked current through the body of the user. The comparator is adapted to generate a first output signal indicative of the test current, and the controller, when in testing mode, is adapted: to maintain power from the first power supply to the heating arrangement upon receipt of the first output signal, and to adjust the first power supply circuit if no first output signal is received. The underwater use of the heatable clothing garment poses specific problems. Different contents of salts, minerals and other substances such as organic materials and impurities in the water affect the electrical conductivity of the water. The more dissolved substances or ions there are in the water, the higher the conductivity.

Thus, the risk for electrical shock due to a leaked current that travel through water from a garment with electrical heating in an underwater application is dependent on the electrical conductivity of the water.

High security equipment for underwater use teaches the use of an insulated electrical conductor for the safe transportation of any electrical currents. However, in an underwater application a test current transported through an insulated electrical conductor will not simulate the true environment where a leaked current is transported though the water. The electrical conductivity of the water in which the user with the garment is submerged have to be taken into consideration by a protection device to adapt the result to the true conductivity of the water.

The present invention teaches that the body of water in which the user is submerged enables the galvanic contact between the body of the user and the testing electrode.

This will enable the use of the water, with its specific conductivity, to be a part of the closed circuit for the test current.

The threshold value may be set to a value that is lower than a potential difference that is safe and comfortable for the human body.

It is proposed that the threshold value may be smaller than a leaked current of 1 mA.

The protection device may comprise at least one sensing electrode, at least one electrical comparator and a controller.

The sensing electrode can be adapted to make a galvanic contact with the skin of the user, and may be adapted to be set to an electrical potential in relation to a common ground with the first power supply circuit.

The electrical comparator may be configured to detect a leaked current from the heating arrangement, causing any difference between the electrical potential and a reference potential, and to generate the first output signal indicative of the difference.

The protection device may comprise a second power supply circuit configured to supply required power to the comparator. In one aspect of the invention the first and second power supply circuit is the same power supply circuit.

It is proposed that the protection device may comprise several sensing electrodes and corresponding comparators, and that the controller is adapted to receive a first output signal from either one of these comparators. The controller may then be configured to adjust the first power supply circuit if a first output signal from any comparator indicates a potential difference that exceeds the threshold value.

The self-test device may further comprise a switching device which may be configured to switch the self-test device between the non-testing mode and the testing-mode based on at least one parameter, such as a time interval, and/or a signal generated by a dial operated by the user.

In one embodiment of the proposed invention, it is equipped a comparing sensor able to detect leaked current. The comparing sensor is adapted to compare an outgoing current from the first power supply circuit to the heating arrangement with a returning current from the heating arrangement to the first power supply circuit. The comparing sensor is configured as to detect any difference between the outgoing current and the returning current and to generate a second output signal indicative of the difference. Suitably, the controller is adapted to adjust the first power supply circuit on receipt of the second output signal from the comparing sensor.

The controller may be adapted to make the adjustment by decreasing the output power, where the decreased output power is safe and comfortable when passed through the body of a user. In another aspect of the invention the controller may be adapted to make the adjustment by disconnecting, or turning off, the first power supply circuit.

In one aspect of the invention the protection device may be an integrated part of the power supply circuit and/or heatable clothing garment. In another aspect of the invention the protection device may be a standalone device adapted to function with any power supply circuit and heatable clothing garment.

### Advantages

The advantages that foremost may be associated with a protection device according to the present invention is that the risk of electrical shock to a user of an electrically heatable clothing garment, in case of malfunction, is mitigated.

The inventive protection device is able to reliably detect current passing through the body of a person utilizing the protection device. This has a number of advantageous effects, including enabling for heatable clothing to be designed for a higher power consumption and as such have increased heating capacity and more even heating distribution. The increased heating capacity enables for heatable clothing to be designed with less insulation resulting in increased maneuverability.

The protection device is also in one aspect of the invention improved regarding the accuracy in which the protection device is able to detect leaked current.

The inventive protection device comprises a self-test device with the advantageous effects of increasing the safety of the user, since the self-test device enables for the detection of a malfunction in the protection device. The invention specifically teaches that the galvanic contact between the testing electrode of the self-test device and the body of the user is enabled through the body of water, which brings the advantage of including the conductivity of the water into the self-test circuit.

In another embodiment of the proposed invention, it comprises a comparing sensor utilizing an alternative method of detecting leaked current. This has the advantageous effect of increasing the safety of the user, since in case of sensing electrode-, or comparator malfunction there is an alternative comparing sensor which is able to detect a leakage of current.

In one embodiment of the invention the protection device may be a standalone device adapted to function with any power supply circuit and heatable clothing garment. One advantageous effect of this embodiment is that it allows for a wide range of heatable clothing manufacturers to incorporate the protection device into their clothing. Another advantageous effect is that it enables for the user to choose when to utilize the protection device.

### BRIEF DESCRIPTION OF THE DRAWINGS

A protection device for controlling a power supply circuit for powering a heating arrangement belonging to a heatable clothing garment according to the present invention will now be described in detail with reference to the accompanying drawings, in which:

FIG. 1 shows a schematic illustration of the inventive protection device,

FIG. 2 shows a schematic illustration of the inventive protection device comprising two sensing electrodes a second power supply adapted to supply power to a comparator,

FIG. 3 shows a schematic illustration of the inventive protection device comprising a self-test device,

FIG. 4 shows a schematic illustration of the inventive protection device comprising a self-test device in which the heatable clothing garment and protective device is adapted as to be submerged in a body of water,

FIG. 5 shows a schematic illustration of the inventive protection device comprising a self-test device and a comparing sensor,

FIG. 6 shows a schematic illustration of the inventive protection device as an integrated part of a power supply circuit and/or a heatable clothing garment,

FIG. 7 shows a schematic illustration of a protection device which as a standalone device adapted as to function with any power supply circuit and heatable clothing garment.

### DETAILED DESCRIPTION OF PREFERRED EMBODIMENTS

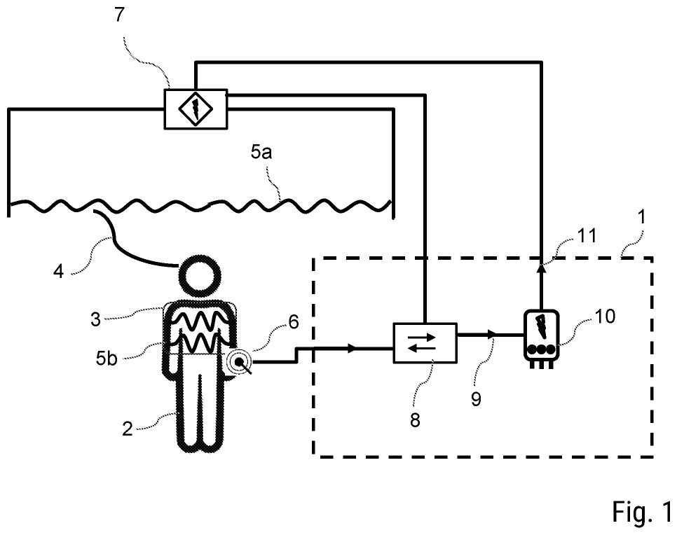

In the following, the present invention will be described with a reference to FIG. 1 showing a protection device 1 for protecting a user 2 of an electrically heatable clothing garment 3 against a leaked current 4 from a heating arrangement 5a, 5b of the heatable clothing garment 3. In FIG. 1 the heating arrangement 5a, 5b is illustrated schematically 5a as well as figuratively 5b.

The invention is adapted to function with electrically heatable clothing garments 3 where sufficient power is provided into the heating arrangement 5 to enable heating in extreme whether scenarios or cold conditions, and the purpose of the invention is to enable such high-powered heating without putting the user 2 into jeopardy.

The purpose of the inventive protection device 1 is to ensure the safety of the user 2 from leaked current 4 from a heating arrangement 5 in the scenario of a malfunction that would cause a leaked electric current 4 to flow from the heating arrangement 5 into the body of the user 2.

The protection device 1 is adapted to detect a leaked electric current 4 from the heating arrangement 5 into the body of the user 2. The protection device 1 comprises at least one sensing electrode 6, where the embodiment according to FIG. 1 comprises one sensing electrode 6. The sensing electrode 6 is adapted to make a galvanic contact with the skin of the user 2. The sensing electrode 6 is adapted to be set to an electrical potential in relation to a common ground with a first power supply circuit 7. In the embodiment according to FIG. 1 the sensing electrode 6 is adapted to make galvanic contact with the wrist of the user 2. The sensing electrode 6 could, however be adapted to make galvanic contact at the neck, ankle, chest, legs or any other part of the user 2.

The protection device 1 further comprises an electrical comparator 8 which is configured to detect a leaked current 4 from the heating arrangement 5a, 5b into the body of the user, causing any difference between the electrical potential and a reference potential, and to generate a first output signal 9 indicative of the difference.

The protection device 1 further comprises a controller 10 which is adapted: to receive the first output signal 9 from the comparator 8, and to adjust 11 the first power supply circuit 7 when the first output signal 9 indicates a potential difference exceeding a threshold value.

Suitably, the threshold value is set to a value that is lower than a potential difference that is safe and comfortable for the human body. The purpose of the invention is primarily safety for the user 2; thus, the threshold must be set to a value where safety is guaranteed. The heatable clothing garment 3 may also be used in environments where it is critical that the user 2 is not disturbed or distracted, hence the threshold may also be set to a value where a leaked current 4 is not even causing discomfort or concern in any way to the user 2. It can even be set so low so that the leaked current 4 is not even detectable by the user 2.

When it comes to “safe” and “comfortable” it is known that an electrical current of circa 1 mA is perceptible to the human body, however, this varies greatly between individuals, and is highly dependent on surrounding factors such as environment, skin conductivity and more. One factor that will influence this perceptivity is if the user is in a dry environment, or if the user is wet from humidity, rain or sweat. The user may even be totally submerged in water while wearing the heatable clothing garment, which again will influence at what level a leaked electrical current can be considered safe or comfortable. The proposed threshold value may be set to 1 mA, but it should be understood that this can be adapted to environmental circumstances for the use of the heatable clothing garment, and to personal preferences of the user.

There are different known general principles for comparators, and one proposed embodiment of the invention teaches that the comparator 8 is a voltage comparator, if so, the threshold value is suitably a voltage that corresponds to a leaked current that is smaller than e.g. 1 mA. In another proposed embodiment of the invention the comparator 8 is a current comparator, if so, the threshold value is suitably smaller than a leaked current of e.g. 1 mA.

The electrical potential of the sensing electrode 6 may be set to zero. However, according to one proposed embodiment of the invention, the electrical potential of the sensing electrode 6 may be set different from zero, thereby increasing accuracy of the comparator 8.

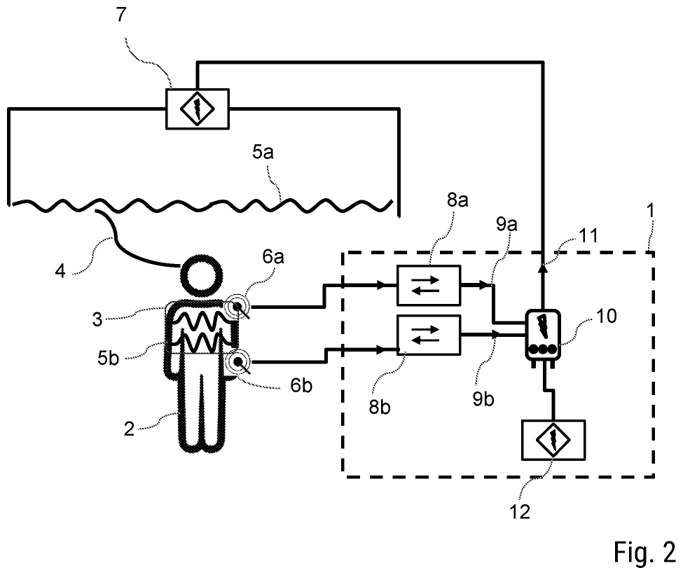

The protection device 1 may in one embodiment, as illustrated in FIG. 2, comprise a second power supply circuit 12 configured to supply required power to the controller 10 and the comparator 8. In another embodiment, as illustrated in FIG. 1, the first power supply circuit 7 provides required power to the controller 10 and the comparator 8, hence and first and second power supply circuit is the same power supply circuit 7.

FIG. 2 illustrates that the protection device 1 may comprise several sensing electrodes 6a, 6b and corresponding comparators 8a, 8b, in which case the controller 10 may be adapted to receive a first output signal 9a, 9b from either one of the comparators 8a, 8b. It is proposed that the controller (10) is configured to adjust 11 the first power supply circuit 7 if a first output signal 9a, 9b from any comparator 8a, 8b indicates a potential difference that exceeds the threshold value.

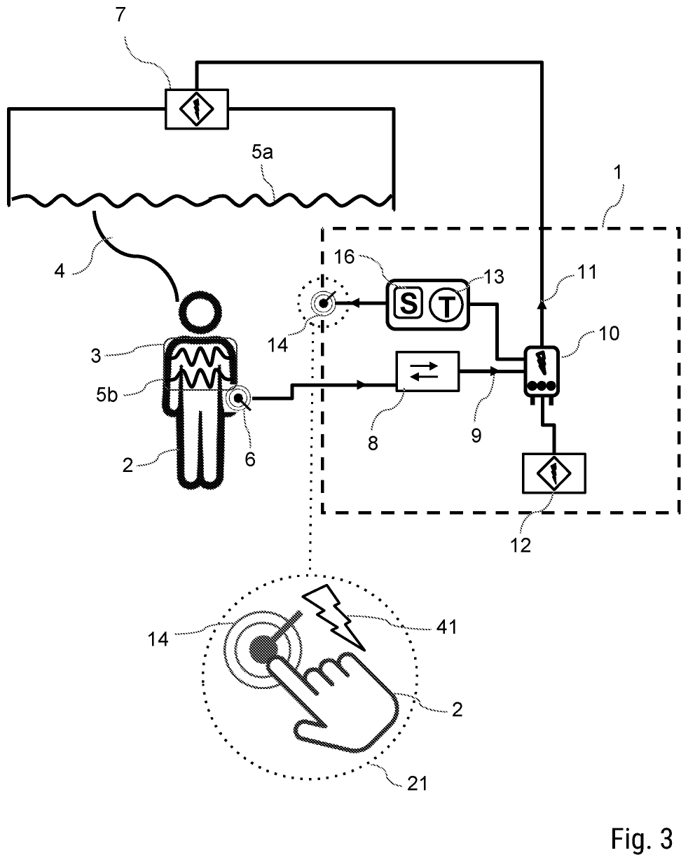

In one aspect of the present invention, as illustrated in FIG. 3, the protection device further comprises a self-test device 13 configured to verify the functionality of the protection device 1 and a correct galvanic contact between the sensing electrode 6 and the skin of the user 2.

Here it can be seen that the self-test device 13 comprises a testing electrode 14 which is adapted to enable a galvanic contact with the body of the user 2. The self-test device 13 is configured to operate in either a non-testing mode or a testing mode. When in the non-testing mode, the testing electrode 14 is at an electrically floating potential. When in the testing mode, the self-test device 13 is configured to set the testing electrode 14 at an electrical potential different from ground that exceeds the threshold value, thus generating an electrical closed-circuit test current 41 simulating a leaked current through the body of the user 2.

The test current 41 simulating a leaked current is picked up by the sensing electrode 6 and causes the comparator 8 to generate a first output signal 9, which when in testing mode is indicative of the test current 41.

When in testing mode, the controller 10 is adapted:
to maintain power from the first power supply 7 to the heating arrangement 5a, 5b upon receipt of the first output signal 9, and
to adjust 11 the first power supply circuit 7 if no first output signal 9 is received.

The testing electrode 14 described in relation to the self-test device 13 may be configured to enable galvanic contact between the body of the user 2 and the testing electrode 14 through a physical touch 21 by the user 2 on the testing electrode 14.

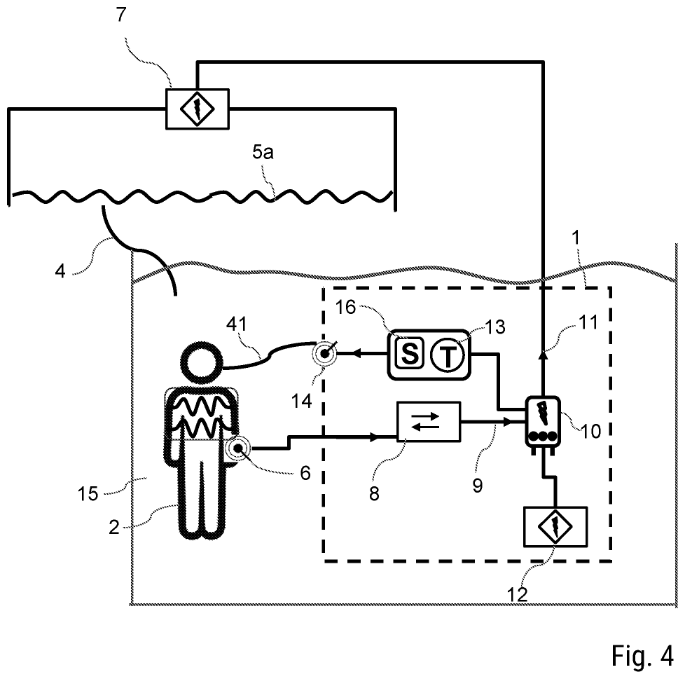

Since the heatable clothing garment 3 and its first power supply circuit 7 are made for use under water, as illustrated in FIG. 4, the protection device 1 is adapted to be submerged in a body of water 15 with its user 2. Hence, the testing electrode 14 is configured to be in galvanic contact with the body of water 15, and adapted so that galvanic contact between the body of the user 2 and the testing electrode 14 is established through the body of water 15. Here it can be seen that the generated test current 41 travels from the testing electrode 14 to the user 2 via the water 15, thus closing the electrical closed-circuit test current 41.

In one proposed embodiment of the present invention, as illustrated in FIGS. 3 and 4, the self-test device 13 further comprise a switching device 16 which is configured to switch the self-test device 13 between the non-testing mode and the testing-mode based on at least one parameter, such as a time interval, and/or a signal generated by a dial operated by the user 2.

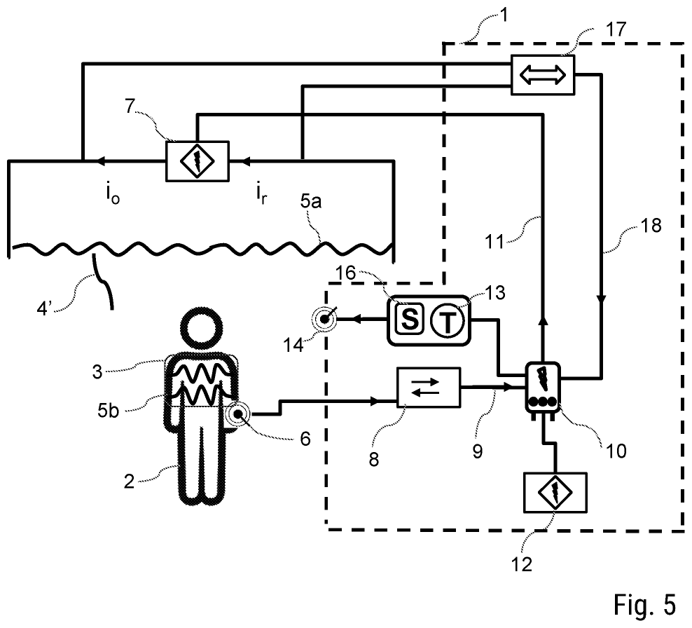

In one proposed embodiment of the present invention, as illustrated in FIG. 5, the protection device 1 is equipped with a comparing sensor 17 which is able to detect a leaked current 4′ regardless of which way this leaked current 4′ takes. The comparing sensor 17 is adapted to compare an outgoing current iₒ from the first power supply circuit 7 to the heating arrangement 5a, 5b with a returning current iᵣ from the heating arrangement 5a, 5b to the first power supply circuit 7. The comparing sensor 17 is configured as to detect any difference between the outgoing current iₒ and the returning current iᵣ and to generate a second output signal 18 indicative of the difference. It is proposed that the controller 10 is adapted to adjust 11 the first power supply circuit 7 on receipt of the second output signal 18 from the comparing sensor 17.

As shown above, the controller 10 is adapted to make an adjustment 11 of the first power supply 7 upon receipt of the first output signal 9 or second output signal 18. The purpose of this adjustment 11 is primarily to maintain safety for the user, and in some cases also to maintain comfort for the user. Hence this adjustment 11 can be done in different ways. One aspect of the invention teaches that the adjustment 11 is done by decreasing the output power, where the decreased output power is safe and comfortable when passed through the body of a user. In another aspect of the invention the controller may be adapted to make the adjustment 11 by disconnecting the first poser circuit 7 from the heating element 5, or by turning the first power supply circuit 7 off.

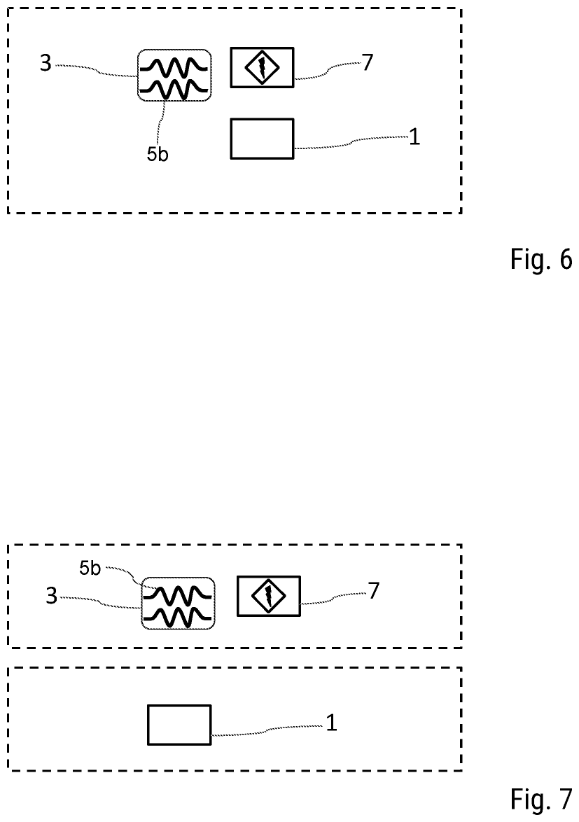

It is not uncommon to manufacture heatable clothing garments with standalone power supply circuits, as to enable easy replacement of discharged or degenerated batteries as well as to allow for a heatable clothing garment to integrate with a wide arrange of batteries. The proposed protection device 1 can in a similar manner be either an integrated part of the power supply circuit 7 and/or heatable clothing garment 3, as illustrated in FIG. 6, or be offered as a standalone device adapted to function with any power supply circuit 7 and/or heatable clothing garment 3, as illustrated in FIG. 7. Having the protection device 1 offered as a standalone device has the advantageous effect of enabling retrofitting of existing heatable clothing garments 3 with the protection device 1, thus enabling for a high voltage and/or current to be applied to the heating arrangement 5 under safe conditions.

It will be understood that the invention is not restricted to the afore described and illustrated exemplifying embodiments thereof and that modifications can be made within the scope of the invention as defined by the accompanying Claims.

1. A protection device for controlling a first power supply circuit for powering a heating arrangement belonging to a heatable clothing garment, where said protection device, first power supply circuit, and clothing garment are adapted to be submerged in a body of water with its user, wherein said protection device is adapted to detect a leaked electric current from said heating arrangement into a body of the user of said clothing garment, wherein said protection device comprises:
at least one sensing electrode adapted to make a galvanic contact with the skin of said user;
a controller adapted to adjust said first power supply circuit when a first output signal indicates a difference in electrical potential exceeding a threshold value, the potential difference being caused by a leaked current, leaked from said heating arrangement; and
a self-test device configured to verify a functionality of said protection device, where said self-test device comprises a testing electrode adapted to enable a galvanic contact with the body of said user through the body of water, said self-test device is configured to operate in either a non-testing mode or a testing mode, that, when in said non-testing mode, said testing electrode is at an electrically floating potential, and when in said testing mode, said self-test device is configured to set said testing electrode at an electrical potential different from ground that exceeds said threshold value, thus generating an electrical closed-circuit test current simulating a leaked current through the body of said user, wherein a comparator is adapted to generate a first output signal indicative of said test current, and that said controller, when in testing mode, is adapted;
to maintain power from said first power supply circuit to said heating arrangement upon receipt of said first output signal; and
to adjust said first power supply circuit if no first output signal is received.

2. The protection device according to claim 1, wherein said threshold value is set to a value that is lower than a potential difference that is safe and comfortable for the human body.

3. The protection device according to claim 2, wherein said threshold value is smaller than a leaked current of 1 mA.

4. The protection device according to claim 1, wherein
said sensing electrode is adapted to be set to an electrical potential in relation to a common ground with said first power supply circuit, and
said protection device further comprising an electrical comparator configured to detect said leaked current causing any difference between said electrical potential and a reference potential, and to generate said first output signal indicative of said difference.

5. The protection device according to claim 4, wherein said protection device comprises a second power supply circuit configured to supply required power to said comparator.

6. The protection device according to claim 5, wherein the first and second power supply circuit is the same power supply circuit.

7. The protection device according to claim 4, wherein the protection device comprises several sensing electrodes and corresponding comparators, and the controller is adapted to receive a first output signal from either one of said comparators, and configured to adjust the first power supply circuit if a first output signal from any comparator indicates a potential difference that exceeds said threshold value.

8. The protection device according to claim 1, wherein said self-test device further comprises a switching device configured to switch said self-test device between said non-testing mode and said testing-mode based on at least one parameter, such as at least one of a time interval and a signal generated by a dial operated by the user.

9. The protection device according to claim 1, wherein a comparing sensor is adapted to compare the outgoing current from said first power supply circuit to said heating arrangement with the returning current from said heating arrangement to said first power supply circuit, that the comparing sensor is configured to detect any difference between said outgoing current and said returning current and to generate a second output signal indicative of said difference, and that said controller is adapted to adjust said first power supply circuit on receipt of said second output signal from said comparing sensor.

10. The protection device according to claim 1, wherein said controller is adapted to make said adjustment by decreasing said output power, where said decreased output power is safe and comfortable.

11. A The protection device according to claim 1, wherein said controller is adapted to make said adjustment by disconnecting, or turning off, said first power supply circuit.

12. The protection device according to claim 1, wherein said protection device is an integrated part of at least one of said first power supply circuit and the heatable clothing garment.

13. The protection device according to claim 1, wherein said protection device is a standalone device adapted to function with at least one of any power supply circuit and/or the heatable clothing garment.
